(19) United States
(12) Patent Application Publication
(10) Pub. No.: US 2016/0379797 A1
(43) Pub. Date: Dec. 29, 2016

(54) Charged Particle Beam Apparatus

(71) Applicant: HITACHI HIGH-TECNOLOGIES CORPORATION, Tokyo (JP)

(72) Inventors: Tsunenori NOMAGUCHI, Tokyo (JP); Toshihide AGEMURA, Tokyo (JP); Zulihuma YASENJIANG, Tokyo (JP)

(21) Appl. No.: 14/902,436

(22) PCT Filed: Jun. 25, 2014
(86) PCT No.: PCT/JP2014/066763

§ 371 Date: Dec. 31, 2015

(30) Foreign Application Priority Data
Jul. 31, 2013 (JP) 2013-158434

(51) Int. Cl. H01J 37/244; H01J 37/141; H01J 37/285; H01J 37/22

(52) U.S. Cl. CPC H01J 37/244; H01J 37/226; H01J 37/141; H01J 37/285

(57) ABSTRACT

Disclosed is a charged particle beam apparatus wherein charged particles emitted from a sample are efficiently acquired at a position as close as possible to the sample, said position being in the objective lens. This charged particle beam apparatus is provided with: a charged particle beam receiving surface that is provided with a scintillator that emits light by means of charged particles; a photodetector that detects light emitted from the scintillator; a mirror that guides, to the photodetector, the light emitted from the scintillator; and an objective lens for focusing the charged particle beam to a sample. A distance (Lsm) between the charged particle beam receiving surface and the mirror is longer than a distance (Lpm) between the photodetector and the mirror, and the charged particle beam receiving surface, the mirror, and the photodetector are stored in the objective lens.

### TECHNICAL FIELD

The present invention relates to a charged particle beam apparatus including a detection particle detector for detecting a charged particle which is emitted or reflected from a sample when, for example, the sample is irradiated with a charged particle beam.

### BACKGROUND ART

A scanning electron microscope (SEM) which can perform observation on a nanometer level has been used in various fields such as a semiconductor field, a material field, a biological field. An SEM generally detects a signal electron emitted from a sample by a detector arranged in a sample chamber or a charged particle beam column to thereby acquire an image. Accordingly, an acquired image quality is significantly influenced by a detecting system. Therefore, various systems have been proposed until now, and there are proposed a system in which an electrode for attracting a signal electron is mounted at a front end of a detector (Patent Literature 1), a system using a converting plate (Patent Literature 2), a system using an orthogonal electromagnetic field (Patent Literature 3), a system including a charged particle beam receiving surface in an annular shape (Patent Literature 4), and the like. Further, there has also been made a proposal concerning a position of mounting a detector such that a hole for inserting the detector is provided at a side wall of a front end of a magnetic path for making a magnetic field lens (Patent Literature 5).

### CITATION LIST

### Patent Literature

Patent Literature 1: Japanese Unexamined Patent Application Publication No. 2009-536776

Patent Literature 2: Japanese Unexamined Patent Application Publication No. 2006-004855

Patent Literature 3: International Publication No. WO2000/019482

Patent Literature 4: Japanese Unexamined Patent Application Publication No. 2010-182596

Patent Literature 5: Japanese Unexamined Patent Application Publication No. Hei7(1995)-226180

### SUMMARY OF INVENTION

### Technical Problem

The inventors of the present application have carried out an intensive investigation concerning mounting of a charged particle detector inside a column for irradiating a sample with a charged particle beam. As a result, the following knowledge has been acquired. An explanation will be given as follows by taking an example of an SEM as a charged particle beam apparatus.

In order to improve an image quality of an SEM image, it is necessary to efficiently acquire a number of signal electrons. As an effective method therefor, it is conceivable to arrange a detector at a position proximate to a source of generating a signal electron, that is, a position as proximate to a sample as possible inside an objective lens. However, various parts of an electrode, a coil, a deflector and the like are obliged to arrange inside the objective lens, and it is difficult to ensure a sufficient space at a vicinity of the sample.

An object of the present invention concerns to efficient acquisition of a signal electron emitted from a sample from a position as proximate to the sample as possible inside an objective lens.

### Solution to Problem

The present invention concerns that for example, a charged particle beam receiving surface including a scintillator for emitting light by a charged particle, a photodetector for detecting the light emitted from the scintillator, a mirror for guiding the light emitted from the scintillator to the photodetector, and an objective lens for focusing a charged particle beam to a sample are included, and a distance Lsm between the charged particle beam receiving surface and the mirror is longer than a distance Lpm between the photodetector and the mirror.

Further, the present invention concerns that, for example, a charged particle beam receiving surface including a scintillator for emitting light by a charged particle, a photodetector for detecting the light emitted from the scintillator, a mirror for guiding the light emitted from the scintillator to the photodetector, and an objective lens for focusing the charged particle beam to a sample are included, and in a projection drawing projecting a charged particle detector to a face in parallel with a light receiving face of the photodetector, a clearance is present between the charged particle beam receiving surface and the photodetector.

### Advantageous Effects of Invention

By the present invention, the charged particle beam detector can be installed to a small space inside the objective lens. Also, the charged particle receiving surface can be installed at a position more proximate to the sample than the photodetector.

### BRIEF DESCRIPTION OF DRAWINGS

FIG. 1 is an outline view of a charged particle beam apparatus according to a first embodiment.

FIG. 2 is an outline view of a charged particle detector portion according to the first embodiment (a configuration in which an achromatic transparent acrylic resin or quartz glass is used as a light guide).

FIG. 3 is an outline view of a charged particle detector portion according to the first embodiment (a configuration in which a fiber optic plate is used).

FIG. 4 is an outline view of a charged particle detector portion according to the first embodiment (a configuration in which an optical lens is used).

FIG. 5 is an outline view of a GUI screen according to the first embodiment.

FIG. 6 is an outline view of a charged particle beam apparatus according to a second embodiment.

### DESCRIPTION OF EMBODIMENTS

Embodiments disclose a charged particle beam apparatus including a charged particle beam receiving surface including a scintillator for emitting light by a charged particle, a photodetector for detecting the light emitted from the scintillator, a mirror for guiding the light emitted from the scintillator to the photodetector, and an objective lens for focusing a charged particle beam to a sample, in which a distance Lsm between the charged particle beam receiving surface and the mirror is longer than a distance Lpm between the photodetector and the mirror, and the charged particle beam receiving surface, the mirror, and the photodetector are stored inside the objective lens.

Further, the embodiments disclose a charged particle beam apparatus including a charged particle beam receiving surface including a scintillator for emitting light by a charged particle, a photodetector for detecting the light emitted from the scintillator, a mirror for guiding the light emitted from the scintillator to the photodetector, and an objective lens for focusing a charged particle beam to a sample, in which in a projection drawing projecting a charged particle detector to a face in parallel with a light receiving surface of the photodetector, a clearance is present between the charged particle beam receiving surface and the photodetector, and the charged particle beam receiving surface, the mirror, and the photodetector are stored inside the objective lens.

Further, the embodiments disclose a charged particle detector including a charged particle beam receiving surface including a scintillator for emitting light by a charged particle, a photodetector for detecting the light emitted from the scintillator, and a mirror for guiding the light emitted from the scintillator to the photodetector, in which a distance Lsm between the charged particle beam receiving surface and the mirror is longer than a distance Lpm between the photodetector and the mirror.

Further, the embodiments disclose a charged particle detector including a charged particle beam receiving surface including a scintillator for emitting light by a charged particle, a photodetector for detecting the light emitted from the scintillator, and a mirror for guiding the light emitted from the scintillator to the photodetector, in which in a projection drawing projecting a charged particle detector to a face in parallel with a light receiving face of the photodetector, a clearance is present between the charged particle beam receiving surface and the photodetector.

Further, the embodiments disclose that the charged particle beam apparatus includes a signal amplifying substrate for amplifying an output of the photodetector, in which the signal amplifying substrate is stored inside the objective lens.

Further, the embodiments disclose that the objective lens includes a coil for generating a magnetic field for focusing the charged particle beam, and the charged particle beam receiving surface is installed between an upper face and a lower face of the coil relative to an optical axis of the objective lens. Further, the embodiments disclose that the objective lens includes a coil and a magnetic pole piece for generating a focusing magnetic field and two or more electrodes for generating a focusing electrostatic field, in which one of the electrodes and the charged particle beam receiving surface of the charged particle detector are brought into electric contact with each other via a spring.

Further, the embodiments disclose that the objective lens includes a coil for generating a magnetic field for focusing the charged particle beam, in which the charged particle beam receiving surface is installed at a position more proximate to the sample than the coil relative to an optical axis of the objective lens. Further, the embodiments disclose that the objective lens includes a coil and a magnetic pole piece for generating a focusing magnetic field, and two or more electrodes for generating a focusing electrostatic field, and one of the electrodes and the charged particle beam receiving surface of the charged particle detector are brought into electric contact with each other via a spring. Further, the embodiments disclose that an opening for a light receiving face for inserting the charged particle receiving surface is provided at a side wall of a front end of the objective lens, and the charged particle beam receiving surface is inserted along the opening for the light receiving face. Further, the embodiments disclose that an opening for an optical lens for inserting the optical lens is provided at a side wall of a front end of the objective lens, and the optical lens for guiding the light emitted from the scintillator to the mirror is inserted along the opening for the optical lens. The embodiments disclose that the opening for the light receiving face and the opening for the optical lens are the same opening.

Further, the embodiments disclose that a through hole is perforated to a center of the charged particle beam receiving surface. Further, the embodiments disclose that a beam tube extended by passing through the through hole of the charged particle beam receiving surface, and a mesh are provided, in which an inner face of the beam tube and the charged particle beam receiving surface are electrically insulated from each other, a mesh is present at a vicinity of a front end of the beam tube, and the mesh and the beam tube are brought into electric contact with each other.

Further, the embodiments disclose that a fiber optic plate is provided between the charged particle beam receiving surface and the mirror. The embodiments disclose that a through hole is perforated to a center of the fiber optic plate. Further, the embodiments disclose that a conductive thin film is included at a surface of the fiber optical plate.

Further, the embodiments disclose that an optical lens is included between the charged particle beam receiving surface and the mirror. Further, the embodiments disclose that a through hole is perforated to a center of the optical lens. Further, the embodiments disclose that a conductive film is included at a surface of the optical lens. Further, the embodiments disclose that the optical lens and the mirror are arranged such that a first image face of the charged particle beam receiving surface is placed rearward from the light receiving face of the photo detector.

Further, the embodiments disclose that a concave mirror is used for the mirror.

Further, the embodiments disclose a charged particle beam apparatus including a charged particle beam column for irradiating a sample with a charged particle beam, and a charged particle detector for detecting a charged particle, and including a function of displaying energy when the charged particle detected by the charged particle detector is emitted from the sample, and a direction when the charged particle is emitted. Further, the embodiments disclose that the charged particle beam apparatus includes a function of displaying the energy when the charged particle is emitted as a distance from an origin and a direction when the charged particle is emitted as an inclination.

Further, the embodiments disclose a GUI screen for displaying emission energy when the charged particle is emitted from the sample, and an emission angle when the charged particle is emitted from the sample concerning a charged particle detected by the charged particle detector. Further, the embodiments disclose that the emission energy is displayed as a distance from the origin and the emission angle is displayed as the inclination.

An explanation will be given as follows of above-described and other novel characteristics and effects of the present invention in reference to the drawings. The drawings are used exclusively for understanding the present invention, and do not contract the scope of right.

### First Embodiment

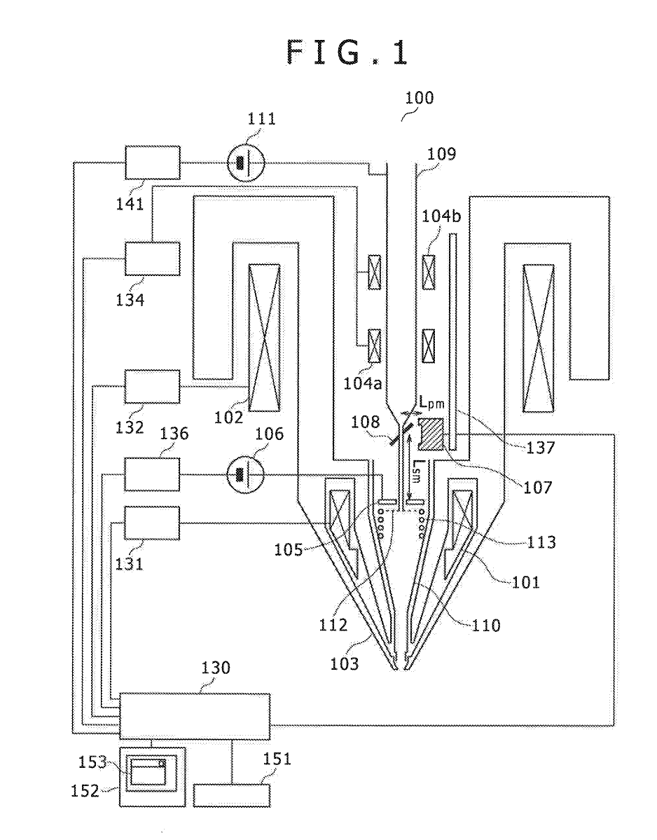

FIG. 1 is an outline view of an objective lens for a charged particle beam (hereinafter, referred to as objective lens) according to the present embodiment.

In FIG. 1, an objective lens 100 includes a coil 101 for out lens as well as a coil 102 for single pole lens for generating a magnetic field for focusing a charged particle beam to a sample, a controller 131 for the coil for out lens and a controller 132 for the coil for single pole lens for controlling the respective coils, a magnetic pole piece 103 for configuring a lens for focusing a charged particle beam by using a magnetic field generated by the respective coils, deflectors 104a and 104b for deflecting the charged particle beam, a deflector controller 134 for controlling the deflectors, a charged particle beam receiving surface 105 including a scintillator for converting a charged particle generated when the sample is irradiated with the charged particle beam into a photon, a power source 106 for the charged particle beam receiving surface for applying a high voltage to the charged particle beam receiving surface, a controller 136 for the power source for the charged particle beam receiving surface for controlling the power source for the charged particle beam receiving surface, a photodetector 107 for detecting a photon generated from the scintillator, a photodetector controller 137 for controlling the photodetector, a mirror 108 for guiding the photon to the photodetector, an upper beam tube 109 and a lower beam tube 110 through which an electron passes, a power source 11 for the beam tube for applying a high voltage to the upper beam tube, a controller 141 for the power source for the beam tube for controlling the power source for the beam tube, a mesh 112 having the same potential as that of the upper beam tube, a spring 113 for bringing the upper beam tube and the lower beam tube into electric contact with each other, an integral computer 130 for integrally controlling the respective control apparatus, a controller (keyboard, mouse and the like) 151 for inputting various instructions of irradiation condition or the like, a position of a sample stage by an operator, and a single or plural display(s) 152 for displaying a GUI screen 153 or a state of the apparatus for controlling the apparatus, acquired information (including image) or the like. Incidentally, the state of the apparatus or the acquired information or the like may be included in the GUI screen 153.

Further, a distance Lsm between the charged particle beam receiving surface 105 and the mirror 108 and a distance Lpm between the photodetector 107 and the mirror 108 are in the following relationship.

Lsm≧Lpm (1)

That is, in a case where the charged particle beam receiving surface 105 is projected to a face in parallel with the photodetector receiving face, a clearance is present between the photodetector and the charged particle beam receiving surface.

Incidentally, the charged particle beam receiving surface is subjected to vapor deposition of aluminum for providing an electrical conductivity.

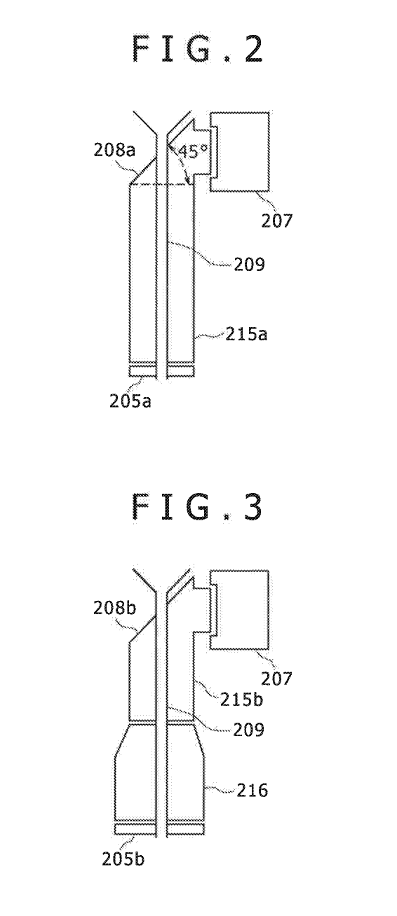

FIG. 2 through FIG. 4 are outline views of charged particle detector portions according to the present embodiment. Specifically, FIG. 2 through FIG. 4 are outline views showing examples of configurations for guiding a photon generated from a scintillator to the photodetector.

FIG. 2 shows a configuration in which achromatic transparent acrylic resin or quartz glass is used as a light guide 215a. By performing vapor deposition or aluminum on an upper face of the light guide which is cut such that a cut face thereof is inclined to the charged particle beam receiving surface 205a by 20° through 60°, in addition to a function as a light guide, also a role of a mirror 208a can be provided. Further, when a path from the mirror 208a to the photodetector 207 is fabricated by the same light guide, the charged particle beam receiving surface 205a can be connected to the photodetector 207 by a single part.

FIG. 3 shows a configuration of using a fiber optic plate (FOP) 216. An FOP is an optical device bundling optical fibers, and a taper type one as shown in FIG. 3 can enlarge or contract an image to be transmitted. That is, photons which are generated from an area wider than a light receiving face of the photodetector 207 can be guided to the photodetector. The charged particles emitted from the sample are widened inside the objective lens, and a way of widening the same is charged by an observing condition. Therefore, it is very important to widen a substantially effective charged particle beam receiving surface 205b for realizing stable detection efficiency. On the other hand, there are a number of parts which are obliged to arrange a coil for a lens, a deflector and the like inside the objective lens as described above, and it is preferable to configure the respective parts as compact as possible. By using the FOP, the wide charged particle beam receiving surface and the compact detector can be made compatible with each other. Incidentally, a light guide 215b having the mirror 208b is used from the FOP to the photodetector similar to FIG. 2.

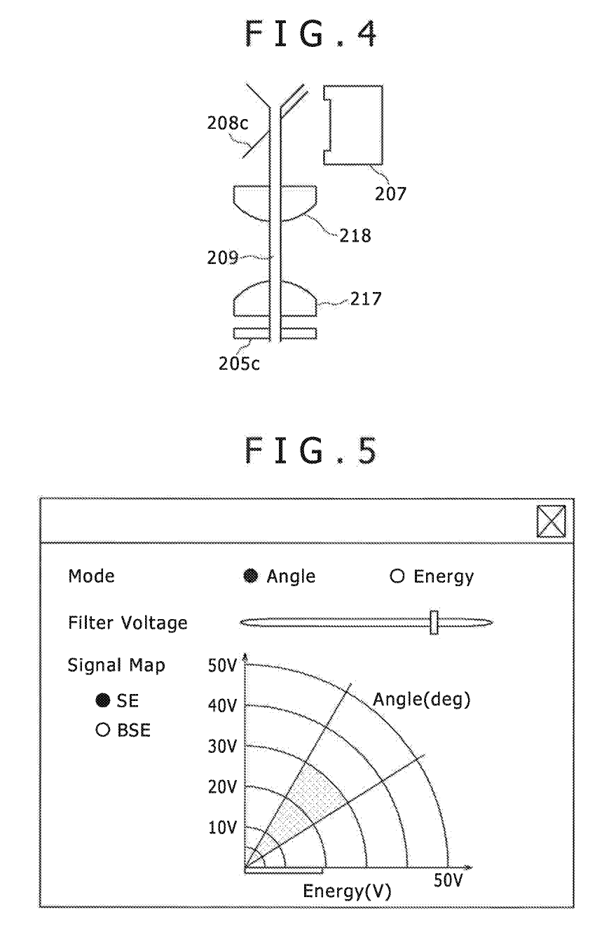

FIG. 4 shows a configuration of guiding a photon generated from the scintillator to a photodetector 207 via a mirror 208c by using optical lenses. Similarly to the FOP, a substantially effective charged particle beam receiving surface 205c can be made wider than the light receiving face of the photodetector, and the wide charged particle beam receiving surface and the compact detector can be made compatible with each other. Also, in a case of using optical lenses, an effective charged particle beam receiving surface can be changed by configuring the optical lenses to be able to drive in an optical axis direction of the objective lens. That is, a distribution of detected signal electrons can be changed. Further, although in the present configuration, a first optical lens 217 and a second optical lens 218 are used, in an object of guiding a photon generated from the scintillator to the photodetector, the number of sheets of optical lenses is not problematic. Further, also loss of photons by the beam tube 209 can be reduced by combining optical lenses such that an image of the charged particle beam receiving surface is not configured on the optical axis of the objective lens. Preferably, the lenses may be combined such that the image of the charged particle beam receiving surface is configured remotely from the receiving surface of the photodetector.

Further, although in FIG. 2 through FIG. 4, a single beam tube 209 is penetrated from the mirror to the charged particle beam receiving surface such that the charged particle beam is not exposed to an electrical insulator, the charged particle beam may be prevented from being exposed to an electrical insulator by subjecting the light guide, the FOP, and the optical lens to a surface treatment of configuring a conductive film such as a metallizing treatment or a NESA treatment. Also, the beam tube may be divided into plural beam tubes, or both of the beam tube and the surface treatment may be used.

Further, although in the present embodiment, the flat mirror is used, a concave mirror may be used. In that case, similar to the FOP or the optical lens, photons which are generated from an area wider than the receiving face of the photodetector may be guided to the photodetector.

Further, the objective lens is not limited to that of a magnetic field type, and the objective lens of an electrostatic type will do, or a magnetic field electrostatic composite objective lens will do.

A technical effect of a configuration according to the present embodiment is as follows.

First, a charged particle emitted from the sample can efficiently be detected by arranging a charged particle beam receiving surface at a position more proximate to a sample than a photodetector beam receiving surface. Therefore, an improvement in an image quality of a scanning charged particle beam image can be expected. Also, since the charged particle beam receiving surface is arranged on an optical axis of the objective lens 100, an advantage that energy or an angle of emission of a detected charged particle is easy to analyze is achieved. This point facilitates an analysis of image information and amounts to improved usability. Further, a detector portion can compactly be arranged by storing the photo detector 107 inside the objective lens. As a result, the detector can be mounted without perforating a big hole at a magnetic path. Further, in an FIB-SEM apparatus in which a focusing ion beam (FIB) apparatus and an SEM are mounted to a single sample chamber, since two of charged particle beam columns are mounted, a space at a vicinity of the sample is further restricted. Therefore, an advantage of compactly arranging the detector portion is more significant in a composite charged particle beam apparatus including plural charged particle beam columns. Further, a noise generated between the photodetector 107 and the photodetector controller 137 can be reduced by storing also the photodetector controller 137 collectively inside the objective lens.

Next, a voltage applied on the upper beam tube 109 and a voltage applied on the charged particle beam receiving surface 105 can be controlled independently from each other by arranging the mesh 112 having the potential the same as that of the upper beam tube 109 on a lower side of the charged particle beam receiving surface 105. This aspect is very effective in a composite objective lens which is mounted with both of an out lens and a single pole lens. Because although in an out lens mode, both of a focusing operation of a charged particle beam and a detecting function of a charged particle are improved by applying high voltages on both of the beam tube and the charged particle beam receiving surface, whereas in a single lens mode, it is preferable to apply the ground potential on the beam tube from a view point of the focusing operation of the charged particle beam, it is preferable to apply a high voltage on the charged particle beam receiving surface from a view point of the detecting function. Also, energy discrimination of a charged particle beam can also be carried out by controlling the potential, of the beam tube and the potential of the charged particle beam receiving surface independently from each other. For example, in an SEM, a secondary electron at 30 V or lower can be excluded by applying +8 kV on the charged beam particle receiving surface and −30 V on the beam tube.

Further, although the beam tube potential does not have an influence on sample irradiation energy of the charged particle beam, the beam tube potential effects an influence on a trajectory of the charged particle emitted from the sample. Therefore, an angle distribution of a charged particle arriving at the charged particle beam receiving surface 105 arranged inside the beam tube can be controlled by controlling the potential of the beam tube. At that occasion, the beam tube and the charged particle beam receiving surface may be at the same potential. Also, in a case where energy of an irradiated charged particle beam is high to a degree of sufficiently making the scintillator emit light, and potentials of the beam tube and the charged particle beam receiving surface are controlled independently from each other, both of the energy and the angle can simultaneously be discriminated. For example, in an SEM, in a case where energy of an electron beam irradiated to a sample is set to +5 kV and a voltage of the charged particle beam receiving surface is set to +3 kV, a back-scattered electron having a desired angle of emission can selectively be detected by pertinently adjusting the voltage of the beam tube from −5 kV to +3 kV. These advantages are better than in a system using an orthogonal electromagnetic field which is not suitable for angle discrimination. Further, in carrying out energy and angle discrimination, when there is a GUI screen as shown in FIG. 5, the screen is easy to understand intuitively and conveniently. FIG. 5 shows an example in a case where a mode of carrying out an angle discrimination (a mode of driving the beam tube and the charged particle beam receiving surface at the same potential) is selected, and energy and an angle distribution of a secondary electron detected are displayed. In a distribution diagram (Signal Map) of a detected signal, a distance from an origin designates energy of a secondary electron and a direction from the origin designates an angle. Therefore, FIG. 5 shows that a secondary electron having energy of 30 V or lower and an emission angle of 30° through 60° is detected. Incidentally, when aiming to display a distribution diagram of a detected signal to be easy to understand visually, a style thereof is not problematic. For example, a distribution diagram setting the abscissa to the energy and the ordinate to the angle may be formed, or coordinates of the charged particle beam receiving surface may be set by the ordinate and the abscissa, and a point colored by the energy or the angle may be plotted.

Next, consider a method of bringing the upper beam tube 109 and the lower beam tube 110 into electric contact with each other. In order to firmly bring the upper beam tube and the lower beam tube into electric contact with each other, it is necessary to directly fix the lower beam tube to the upper beam tube by a screw or the like, or connect the upper beam tube and the lower beam tube by a cable or the like. The former has an advantage that even when once the upper beam tube and the lower beam tube are connected, attachment or detachment thereof is comparatively easy. The latter has an advantage that it is not necessary to ensure a space for arranging a fixing screw to the upper beam tube and the lower beam tube. Further, in a case of contact by a spring, a dimensional tolerance of the upper tube and the lower beam tube is absorbed by a flexibility of the spring, and therefore, the upper beam and the lower beam tube can individually be fixed. As a result, the detector portion can be handled as an independent unit. This amounts to an improvement in maintenance performance.

### Second Embodiment

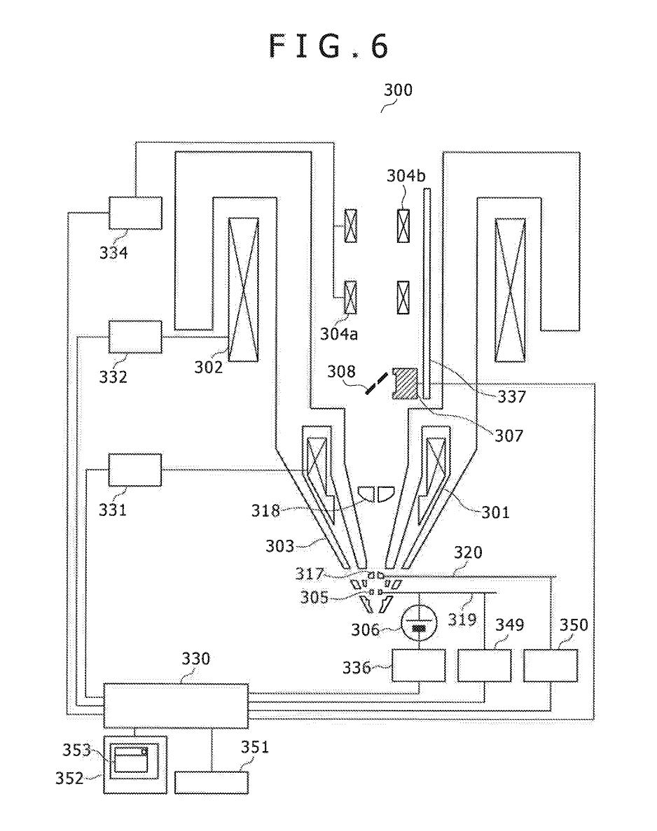

FIG. 6 is an outline view of an objective lens according to the present embodiment. An explanation will be given as follows centering on a difference from the first embodiment.

In FIG. 6, an objective lens 300 includes a coil 301 for out lens and a coil 302 for single pole lens for generating a magnetic field for focusing a charged particle beam to a sample, a controller 331 for the coil for out lens and a controller 332 for the coil for single pole lens for controlling the respective coils, a magnetic pole piece 303 for configuring a lens for focusing a charged particle beam by using a magnetic field generated by the respective coils, deflectors 304a and 304b for deflecting the charged particle beam, a deflector controller 334 for controlling the deflectors, a charged beam particle beam receiving surface 305 including a scintillator for converting a charged particle generated when the sample is irradiated with the charged particle beam into a photon, a power source 306 for the charged particle beam receiving surface for applying a high voltage to the charged particle receiving surface, a power source controller 336 for the charged particle beam receiving surface for controlling the power source for the charged particle beam receiving surface, a scintillator supporting rod 319 for supporting the scintillator, a controller 349 for the scintillator supporting rod for controlling the scintillator supporting rod, a photodetector 307 for detecting the photon generated from the scintillator, a photodetector controller 337 for controlling the photodetector, a first optical lens 317 for guiding the photon to the photodetector, an optical lens supporting rod 320 for supporting the first optical lens, an optical lens supporting rod controller 350 for controlling the optical lens supporting rod, a second optical lens 318 and a mirror 308, an integral computer 330 for integrally controlling the respective control apparatus, a controller (keyboard, mouse or the like) 351 for inputting various instructions such as an irradiation condition and a position of a sample stage by an operator, and a single or plural display(s) 352 for displaying a GUI screen 353 for controlling the apparatus, a state of the apparatus, acquired information (including image) and the like. Incidentally, a state of the apparatus or the acquired information or the like may be included in the GUI screen 353.

Incidentally, the charged particle beam receiving surface 305 and the first optical lens 317 can be inserted from holes provided at a front end of the magnetic pole piece 303 as necessary and can be evacuated therefrom when not needed. Further, as the first optical lens, plural optical lenses having different focal lengths may be mounted, or there may be constructed a configuration in which both or either of the first optical lens and the second optical lens is (are) made to be able to be driven in an optical axis direction of the objective lens. Thereby, a substantially effective area of the charged particle beam receiving surface can be changed. That is, a distribution of detected signal electrons can be changed.

Further, although, according to the present embodiment, it is conceived to carry out the insertion or the evacuation by using the controllers, there may be constructed a configuration in which the insertion or the evacuation is carried out manually. Further, although the scintillator and the first optical lens are supported by the separate supporting rods, the scintillator and the first optical lens may be integrated, and may be supported by a single supporting rod. Further, there may be constructed a configuration in which the scintillator and the first optical lens are not fixed to the supporting rods but placed inside the objective lens as necessary, or there may be constructed a configuration in which the scintillator and the first optical lens are fixed inside the objective lens.

Further, also in the present embodiment, similarly to the first embodiment, a beam tube or a mesh may be mounted, and a concave mirror may be used in place of a flat mirror. Further, the objective lens is not limited to that of a magnetic field type, and an objective lens of an electrostatic type will do, or a magnetic field electrostatic composite objective lens will do.

A technical effect of the configuration according to the present embodiment is as follows.

A distance between the charged particle beam receiving surface and the sample can be made shorter than that in the configuration according to the first embodiment, and therefore, a signal electron can be detected further efficiently. Incidentally, in a case of constructing a configuration in which the scintillator and the first optical lens are supported by the supporting rods and can be inserted or evacuated, the hole is perforated at the front end of the magnetic path, and therefore, there may be constructed an objective lens having a structure in which even when a hole is perforated at the front end of the magnetic path, an influence effected on the magnetic field lens is negligible.

### LIST OF REFERENCE SIGNS

100, 300: objective lenses
101, 301: coils for out lens
102, 302: coils for single pole lens
103, 303: magnetic pole pieces
104a, 104b, 304a, 304b: deflectors
105, 205a, 205b, 205c, 305: charged particle beam receiving surfaces
106, 306: power sources for charged particle beam receiving surfaces
107, 207, 307: photodetectors
108, 208a, 208b, 208c, 308: mirrors
109: upper beam tube
110: lower beam tube
111: power source for beam tube
112: mesh
113: spring
130, 330: integral computers
131, 331: controllers for coil for out lens
132, 332: controllers for coil for single pole lens
134, 334: deflector controllers
136, 336: power source controllers for charged particle beam receiving surfaces
137, 337: photodetector controllers
141: controller for power source for beam tube
151, 351: controllers (keyboards, mice or the like)
152, 352: displays
153, 353: GUI screens
209: beam tube
215a, 215b: light guides
216: fiber optic plate (FOP)
217, 317: first optical lenses
218, 318: second optical lenses
319: scintillator supporting rod
320: optical lens supporting rod
349: scintillator supporting rod controller
350: optical lens supporting rod controller

1. A charged particle beam apparatus comprising a charged particle beam receiving surface including a scintillator for emitting light by a charged particle, a photodetector for detecting the light emitted from the scintillator, a mirror for guiding the light emitted from the scintillator to the photodetector, and an objective lens for focusing a charged particle beam to a sample;
wherein a distance Lsm between the charged particle beam receiving surface and the mirror is longer than a distance Lpm between the photodetector and the mirror; and
wherein the charged particle beam receiving surface, the mirror, and the photodetector are stored inside the objective lens.

2. A charged particle beam apparatus comprising a charged particle receiving surface including a scintillator for emitting light by a charged particle, a photodetector for detecting the light emitted from the scintillator, a mirror for guiding the light emitted from the scintillator to the photodetector, and an objective lens for focusing a charged particle beam to a sample;
wherein in a projection drawing projecting a charged particle detector to a face in parallel with a light receiving surface of the photodetector, a clearance is present between the charged particle beam receiving surface and the photodetector; and
wherein the charged particle beam receiving surface, the mirror, and the photodetector are stored inside the objective lens.

3. The charged particle beam apparatus according to claim 1, further comprising a signal amplifying substrate for amplifying an output of the photodetector;
wherein the signal amplifying substrate is stored inside the objective lens.

4. The charged particle beam apparatus according to claim 1,
wherein the objective lens includes a coil for generating a magnetic field for focusing the charged particle beam; and
wherein the charged particle beam receiving surface is installed between an upper face and a lower face of the coil relative to an optical axis of the objective lens.

5. The charged particle beam apparatus according to claim 4,
wherein the objective lens includes the coil and a magnetic pole piece for generating the focusing magnetic field, and two or more electrodes for generating a focusing electrostatic field; and
wherein one of the electrodes and the charged particle beam receiving surface of the charged particle detector are brought into electric contact with each other via a spring.

6. The charged particle beam apparatus according to claim 1,
wherein the objective lens includes a coil for generating a magnetic field for focusing the charged particle beam; and
wherein the charged particle beam receiving surface is installed at a position more proximate to the sample than the coil relative to an optical axis of the objective lens.

7. The charged particle beam apparatus according to claim 6,
wherein the objective lens includes a coil and a magnetic pole piece for generating the focusing magnetic field, and two or more electrodes for generating a focusing electrostatic field; and
wherein one of the electrodes and the charged particle beam receiving surface of the charged particle detector are brought into electric contact with each other via a spring.

8. The charged particle beam apparatus according to claim 1, wherein a through hole is perforated to a center of the charged particle beam receiving surface.

9. The charged particle beam apparatus according to claim 8, further comprising a beam tube extended by passing through the through hole of the charged particle beam receiving surface, and a mesh;
wherein an inner face of the beam tube and the charged particle beam receiving surface are electrically insulated from each other, the mesh is present at a vicinity of a front end of the beam tube, and the mesh and the beam tube are brought into electric contact with each other.

10. The charged particle beam apparatus according to claim 1, wherein a fiber optic lens is included between the charged particle beam receiving surface and the mirror.

11. The charged particle beam apparatus according to claim 10, wherein a through hole is perforated to a center of the fiber optic plate.

12. The charged particle beam apparatus according to claim 11, wherein a conductive thin film is included on a surface of the fiber optic plate.

13. The charged particle beam apparatus according to claim 1, wherein an optical lens is included between the charged particle beam receiving surface and the mirror.

14. The charged particle beam apparatus according to claim 13, wherein a through hole is perforated to a center of the optical lens.

15. The charged particle beam apparatus according to claim 14, wherein a conductive thin film is included on a surface of the optical lens.

16. The charged particle beam apparatus according to claim 13, wherein the optical lens and the mirror are arranged such that a first image face of the charged particle beam receiving surface is placed rearward from a light receiving face of the photodetector.

17. The charged particle beam apparatus according to claim 1, wherein a concave mirror is used for the mirror.

18. The charged particle beam apparatus according to claim 6, wherein an opening for a light receiving face for inserting the charged particle beam receiving surface is provided at a side wall of a front end of the objective lens, and the charged particle beam receiving surface is inserted along the opening for the light receiving face.

19. The charged particle beam apparatus according to claim 18, wherein an opening for an optical lens for inserting the optical lens is provided at a side wall of a front end of the objective lens, and the optical lens for guiding the light emitted from the scintillator to the mirror is inserted along the opening for the optical lens.

20. The charged particle beam apparatus according to claim 19, wherein the opening for the light receiving face and the opening of the optical lens are the same opening.
